(19) United States
(12) Patent Application Publication
(10) Pub. No.: US 2024/0258278 A1
(43) Pub. Date: Aug. 1, 2024

(54) SEMICONDUCTOR PACKAGE INCLUDING STACKED SEMICONDUCTOR CHIPS

(71) Applicant: SAMSUNG ELECTRONICS CO., LTD., SUWON-SI (KR)

(72) Inventors: Hyungchul SHIN, Suwon-si (KR); Won IL LEE, Suwon-si (KR); Hyuekjae LEE, Suwon-si (KR); Enbin JO, Suwon-si (KR)

(21) Appl. No.: 18/500,089

(22) Filed: Nov. 1, 2023

(30) Foreign Application Priority Data
Jan. 31, 2023 (KR) 10-2023-0012802

(51) Int. Cl. H01L 25/065; H01L 23/00; H01L 25/18; H10B 80/00

(52) U.S. Cl. CPC H01L 25/0657; H01L 24/05; H01L 24/06; H01L 24/08; H01L 25/18; H10B 80/00; H01L 24/13; H01L 24/16; H01L 2224/05552; H01L 2224/0557; H01L 2224/05647; H01L 2224/0603; H01L 2224/06181; H01L 2224/08145; H01L 2224/08225; H01L 2224/13109; H01L 2224/13111; H01L 2224/13113; H01L 2224/13117; H01L 2224/1312; H01L 2224/13139; H01L 2224/13147; H01L 2224/13155; H01L 2224/16227; H01L 2225/06544; H01L 2225/06562; H01L 2225/06565; H01L 2924/01058; H01L 2924/1431; H01L 2924/1432; H01L 2924/1433

(57) ABSTRACT

A semiconductor package includes a lower semiconductor chip, a first semiconductor chip, a first through-electrode vertically penetrating the first semiconductor substrate, a first upper pad connected to the first through electrode, a first circuit layer disposed on the lower surface of the first semiconductor substrate, and a first lower pad disposed on a lower surface of the first circuit layer. A second semiconductor chip includes a second through-electrode spaced apart from the first through-electrode and vertically penetrating the second semiconductor substrate. A second upper pad is connected to the second through electrode. A second circuit layer is disposed on the lower surface of the second semiconductor substrate, and a second lower pad is connected to the second through-electrode on the lower surface of the second circuit layer through the second circuit layer and is integrally formed with the first upper pad.

### CROSS-REFERENCE TO RELATED APPLICATIONS

This U.S. non-provisional patent application claims priority under 35 U.S.C. § 119 to Korean Patent Application No. 10-2023-0012802, filed on Jan. 31, 2023, in the Korean Intellectual Property Office, the entire contents of which are hereby incorporated by reference.

### TECHNICAL FIELD

The present disclosure relates to a semiconductor package, and more particularly, to a semiconductor package in which a plurality of semiconductor chips are stacked.

### DISCUSSION OF THE RELATED ART

High-performance, high-speed, and small electronic components have been increasingly in demanded. To satisfy this demand, a packaging technique of providing a plurality of semiconductor chips in a single package has been suggested.

A semiconductor package technique of integrating a plurality of individual components in a single package as well as a technique of reducing a size of an individual component may be used to realize small and light electronic components. In particular, a semiconductor package for processing high-frequency signals should have excellent electrical characteristics as well as a small size.

### SUMMARY

A semiconductor package includes a lower semiconductor chip and a first semiconductor chip and a second semiconductor chip stacked on the lower semiconductor chip. The first semiconductor chip includes a first semiconductor substrate, a first through electrode vertically penetrating the first semiconductor substrate, a first upper pad electrically connected to the first through electrode on an upper surface of the first semiconductor substrate, an upper protective layer at least partially surrounding the first upper pad on the upper surface of the first semiconductor substrate, a first circuit layer disposed on a lower surface of the first semiconductor substrate, and a first lower pad electrically connected to the first through electrode through the first circuit layer on a lower surface of the first circuit layer. The second semiconductor chip includes a second semiconductor substrate, a second through electrode vertically penetrating the second semiconductor substrate, a second upper pad electrically connected to the second through electrode on an upper surface of the second semiconductor substrate, a second circuit layer disposed on a lower surface of the second semiconductor substrate, a second lower pad electrically connected to the second through electrode through the second circuit layer on a lower surface of the second circuit layer, and a lower protective layer at least partially surrounding the second lower pad on the lower surface of the second circuit layer. The lower protective layer is in direct contact with the upper protective layer, and the second lower pad is in contact with the first upper pad to form an integral body. The first through electrode is horizontally spaced apart from the second through electrode, in a plan view.

A semiconductor package includes a first semiconductor chip and a second semiconductor chip disposed on the first semiconductor chip. The first semiconductor chip includes an upper pad disposed on an upper surface of the first semiconductor chip and a first through electrode vertically penetrating the first semiconductor chip and electrically connected to the upper pad. The second semiconductor chip includes a lower pad disposed on a lower surface of the second semiconductor chip and a second through electrode vertically penetrating the second semiconductor chip and connected to the lower pad. The first through electrode is provided on a first region, the second through electrode is provided on a second region, horizontally spaced apart from the first region, and a width of the upper pad is greater than a width of the lower pad.

A semiconductor package includes a lower semiconductor chip and upper semiconductor chips stacked in a zigzag form on the lower semiconductor chip. The upper semiconductor chips include a first semiconductor chip and a second semiconductor chip disposed on the first semiconductor chip. The first semiconductor chip includes a first upper pad disposed on an upper surface of the first semiconductor chip. A first lower pad is disposed on a lower surface of the first semiconductor chip. A first through electrode vertically penetrates the first semiconductor chip and connects the first upper pad and the first lower pad to each other. The second semiconductor chip includes a second upper pad disposed on an upper surface of the second semiconductor chip, a second lower pad disposed on a lower surface of the second semiconductor chip, the second lower pad having a smaller width than the first upper pad, and a second through electrode vertically penetrating the second semiconductor chip and connecting the second upper pad and the second lower pad to each other. The first upper pad and the second lower pad are in direct contact with each other and form an integral body.

### BRIEF DESCRIPTION OF THE DRAWINGS

Example embodiments will be more clearly understood from the following brief description taken in conjunction with the accompanying drawings, wherein:

FIG. 1 is a cross-sectional view of a semiconductor package according to embodiments of the present disclosure;

FIG. 2 is an enlarged view of region ‘A’ of FIG. 1;

FIGS. 3 to 6 are plan views illustrating a pad of a semiconductor package according to embodiments of the present disclosure;

FIG. 7 is a cross-sectional view of a semiconductor package according to embodiments of the present disclosure;

FIG. 8 is a cross-sectional view of a semiconductor package according to embodiments of the present disclosure;

FIG. 9 is an enlarged view of region ‘B’ of FIG. 8;

FIG. 10 is a cross-sectional view of a semiconductor package according to embodiments of the present disclosure;

FIG. 11 is an enlarged view of region ‘C’ of FIG. 10;

FIG. 12 is a cross-sectional view of a semiconductor package according to embodiments of the present disclosure;

FIG. 13 is an enlarged view of region ‘D’ of FIG. 12;

FIG. 14 is a cross-sectional view of a semiconductor package according to embodiments of the present disclosure; and

FIG. 15 is a cross-sectional view of a semiconductor package according to embodiments of the present disclosure.

### DETAILED DESCRIPTION

Hereinafter, a semiconductor package according to the concept of the present disclosure will be described with reference to the drawings.

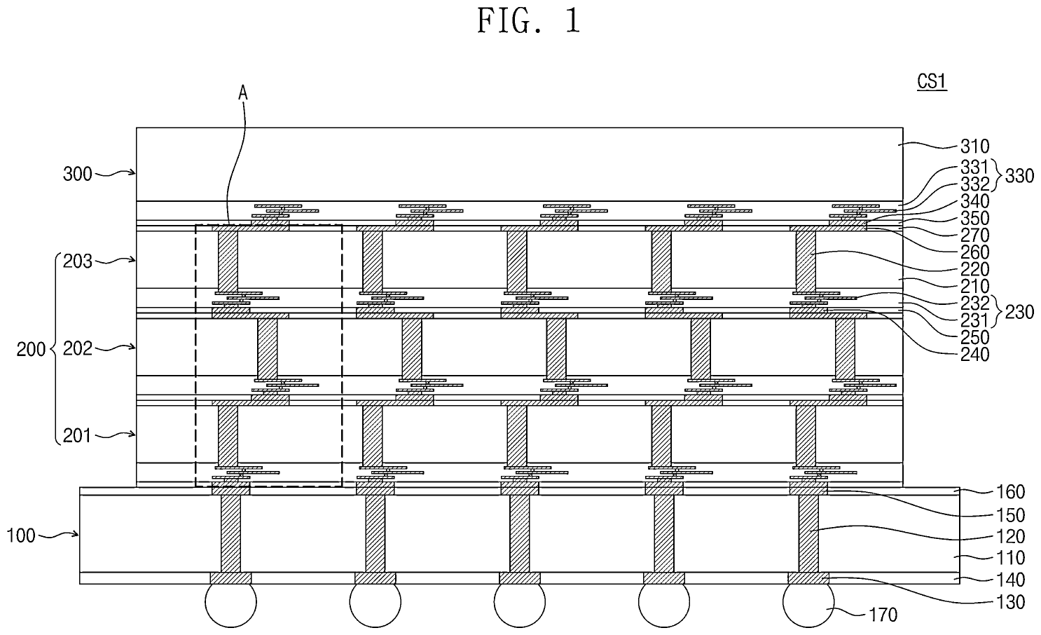

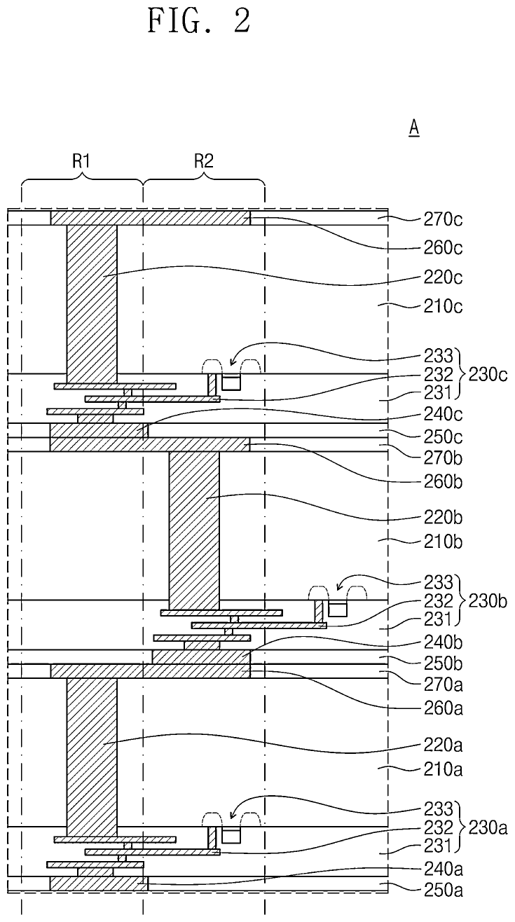

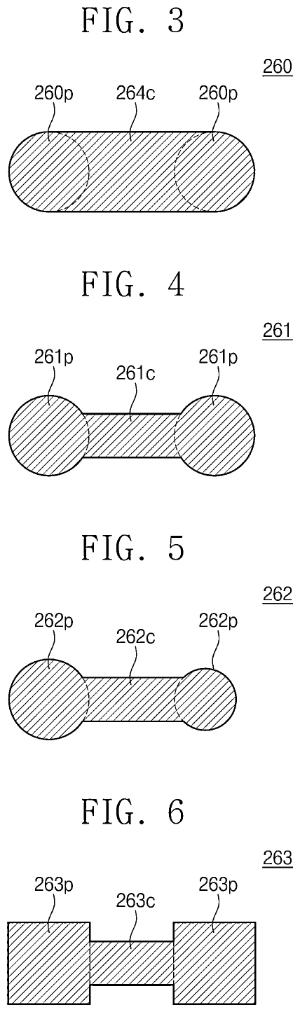

FIG. 1 is a cross-sectional view of a semiconductor package according to embodiments of the present disclosure. FIG. 2 is an enlarged view of region ‘A’ of FIG. 1. FIG. 3 is a plan view illustrating a pad of a semiconductor package according to embodiments of the present disclosure.

Referring to FIGS. 1 to 3, a semiconductor package CS1 may include a lower semiconductor chip 100 and upper semiconductor chips 200. The semiconductor package CS1 may include a first region R1 and a second region R2 horizontally spaced apart from the first region R1. Although FIGS. 1 to 3 illustrate the semiconductor package CS1 is a chip stack including the lower semiconductor chip 100 and four semiconductor chips disposed on the lower semiconductor chip 100, the present disclosure is not necessarily limited thereto. The chip stack may include 4n semiconductor chips, and “n” may be a natural number greater than or equal to 1.

The lower semiconductor chip 100 may include a logic chip, a controller chip, or a buffer chip. However, the present disclosure is not necessarily limited thereto, and the lower semiconductor chip 100 may be a printed circuit board (PCB). For example, the printed circuit board may include a core layer and wiring patterns printed on upper and lower surfaces of the core layer. Hereinafter, it will be described based on an embodiment of FIG. 1.

The lower semiconductor chip 100 may include a lower semiconductor substrate 110, lower through electrodes 120, first conductive pads 130, second conductive pads 150, a first passivation layer 140, and a second passivation layer 160.

The lower semiconductor substrate 110 may be a semiconductor substrate including silicon (Si), germanium (Ge), silicon-germanium (Si—Ge), or the like, or a compound semiconductor substrate. For example, the lower semiconductor substrate 110 may be a silicon substrate. A circuit layer including an integrated element may be provided on the lower surface of the lower semiconductor substrate 110.

The first conductive pads 130 may be provided on the lower surface of the lower semiconductor substrate 110. The first conductive pads 130 may be electrically connected to the integrated element on the lower surface of the lower semiconductor substrate 110. Electrically connected/connected herein includes direct connection/connection or indirect connection/connection through another conductive element. Being electrically connected to the semiconductor chip may mean being electrically connected to integrated circuits of the semiconductor chip. For example, the first conductive pads 130 may include a conductive material such as a metal such as copper (Cu).

The first passivation layer 140 may be provided on the lower surface of the lower semiconductor substrate 110. The first passivation layer 140 may at least partially surround the first conductive pads 130. The first conductive pads 130 may be exposed on the lower surface of the first passivation layer 140. A lower surface of the first passivation layer 140 may be coplanar with a lower surface of the first conductive pads 130. The first passivation layer 140 may include an insulating material such as silicon oxide (SiO), silicon nitride (SiN), and/or silicon carbon nitride (SiCN).

The lower through electrodes 120 may be provided in the lower semiconductor chip 100. The lower through electrodes 120 may vertically penetrate the lower semiconductor substrate 110. The lower through electrodes 120 may be connected to the first conductive pads 130, respectively. The lower through electrodes 120 may include a conductive material such as copper (Cu), titanium (Ti), tungsten (W), and/or a combination thereof.

The second conductive pads 150 may be provided on the upper surface of the lower semiconductor substrate 110. Lower surfaces of the second conductive pads 150 may be provided on upper surfaces of the lower through electrodes 120. The second conductive pads 150 may be connected to the lower through electrodes 120. For example, the first conductive pads 130 and the second conductive pads 150 may be electrically connected through the lower through electrodes 120, respectively. For example, the second conductive pads 150 may include a conductive material such as a metal such as copper (Cu).

The second passivation layer 160 may be provided on the upper surface of the lower semiconductor substrate 110. The second passivation layer 160 may at least partially surround the second conductive pads 150. The second conductive pads 150 may be exposed on an upper surface of the second passivation layer 160. The upper surface of the second passivation layer 160 may be coplanar with the upper surface of the second conductive pads 150. The second passivation layer 160 may include an insulating material such as silicon oxide (SiO), silicon nitride (SiN), and/or silicon carbon nitride (SiCN).

First chip connection terminals 170 may be provided on the lower surface of the lower semiconductor chip 100. The first chip connection terminals 170 may be disposed on the lower surfaces of the first conductive pads 130, respectively. The first chip connection terminals 170 may include solder balls or solder bumps. The first chip connection terminals 170 may include tin (Sn), silver (Ag), copper (Cu), nickel (Ni), bismuth (Bi), indium (In), antimony (Sb), or cerium (Ce), or a combination thereof.

The upper semiconductor chips 200 may be provided on the upper surface of the lower semiconductor chip 100. Side surfaces of the upper semiconductor chips 200 may be vertically aligned with each other. A width of each of the upper semiconductor chips 200 may be smaller than that of the lower semiconductor chip 100. The upper semiconductor chips 200 may be different types of semiconductor chips from the lower semiconductor chip 100. For example, the upper semiconductor chips 200 may include memory chips. Each of the upper semiconductor chips 200 may include a semiconductor substrate 210, a through electrode 220, a circuit layer 230, a lower pad 240, a lower protective layer 250, an upper pad 260, and an upper protective layer 270. Hereinafter, the configuration will be described based on one upper semiconductor chip 200.

The semiconductor substrate 210 may be a semiconductor substrate including silicon (Si), germanium (Ge), silicon-germanium (Si—Ge), or the like, or a compound semiconductor substrate. For example, the semiconductor substrate 210 may be a silicon substrate.

The circuit layer 230 may be provided on a lower surface of the semiconductor substrate 210. The lower surface of the upper semiconductor chip 200 may be an active surface, and an upper surface of the upper semiconductor chip 200 may be an inactive surface. The circuit layer 230 may include an insulating layer 231, a wiring pattern 232, and an integrated element 233.

The integrated element 233 may be provided on the lower surface of the semiconductor substrate 210. An arrangement of the integrated elements 233 is not necessarily limited to that shown, and a plurality of integrated elements 233 may be provided. The integrated element 233 may include a memory circuit, a logic circuit, or a combination thereof. As shown, the integrated element 233 is a planar transistor, but the present disclosure is not necessarily limited thereto. The integrated element 233 may include a gate all around (GAA) type transistor or a vertical type transistor, or may include a passive element such as a resistor or a capacitor together with them.

The insulating layer 231 may be provided on the lower surface of the semiconductor substrate 210. The insulating layer 231 may cover the integrated element 233. The insulating layer 231 may include a single layer or a plurality of mutually stacked layers. The insulating layer 231 may include, for example, silicon oxide, silicon nitride, and/or silicon oxynitride.

The wiring pattern 232 may be provided in the insulating layer 231. The wiring pattern 232 may include a wiring portion and a via portion. The wiring portion may be a wiring pattern extending horizontally within the insulating layer 231. The via portion may be a wiring pattern that vertically penetrates a portion of the insulating layer 231 and is connected to the wiring portion. The wiring pattern 232 may be connected to the integrated element 233. The wiring pattern 232 may include copper (Cu), aluminum (Al), tungsten (W), and/or titanium (Ti).

The lower pads 240 may be provided on the lower surface of the circuit layer 230. The lower pads 240 may be connected to the wiring pattern 232 exposed on the lower surface of the circuit layer 230. The lower pads 240 may include, for example, a conductive material such as a metal such as copper (Cu).

The lower protective layer 250 may be provided on a lower surface of the circuit layer 230. The lower protective layer 250 may cover the lower surface of the circuit layer 230 and may at least partially surround the lower pads 240. The lower pads 240 may be exposed on a lower surface of the lower protective layer 250. A lower surface of the lower protective layer 250 may be coplanar with lower surfaces of the lower pads 240. The lower protective layer 250 may include, for example, an insulating material such as silicon oxide (SiO), silicon nitride (SiN), and/or silicon carbon nitride (SiCN).

The through electrodes 220 may be provided inside the upper semiconductor chip 200. The through electrodes 220 may vertically penetrate portions of the semiconductor substrate 210 and the insulating layer 231. The through electrodes 220 may vertically penetrate at least a portion of the insulating layer 231 and be connected to the wiring pattern 232. Alternatively, the through electrodes 220 might not penetrate the insulating layer 231 and may be connected to the wiring pattern 232 exposed on the upper surface of the insulating layer 231. The through electrodes 220 may be spaced apart from each other. Upper surfaces of the through electrodes 220 may be coplanar with the upper surface of the semiconductor substrate 210. The through electrodes 220 may include, for example, copper (Cu), aluminum (Al), tungsten (W), and/or titanium (Ti).

The upper pads 260 may be provided on the upper surface of the semiconductor substrate 210. The upper pads 260 may be connected to through electrodes 220, respectively. A width of each of the upper pads 260 may be greater than a width of each of the lower pads 240. In a plan view, the upper pads 260 may have pad portions 260p and a connection portion 264c. The pad portions 260p may include a first pad portion and a second pad portion horizontally spaced apart from each other. The first pad portion may be in contact with the through electrodes 220. The second pad portion may be in contact with the lower pads 240 of another upper semiconductor chip 200 adjacent thereto. The connection portion 264c may be a portion connecting the pad portions 260p. A diameter of the pad portions 260p may be the same as a width of the connection portion 264c. The diameter of each of the pad portions 260p may be greater than a diameter of each of the through electrodes 220. The upper pads 260 may include, for example, a conductive material such as a metal such as copper (Cu).

The upper protective layer 270 may be provided on the upper surface of the semiconductor substrate 210. The upper protective layer 270 may at least partially surround the upper pads 260. The upper protective layer 270 may expose upper surfaces of the upper pads 260. The upper protective layer 270 may include, for example, an insulating material such as silicon oxide (SiO), silicon nitride (SiN), and/or silicon carbon nitride (SiCN).

An arrangement of each of the upper semiconductor chips 200 including the above configurations will be described. The upper semiconductor chips 200 may include a first semiconductor chip 201, a second semiconductor chip 202, and a third semiconductor chip 203.

The first semiconductor chip 201 may be provided on the lower surface of the lower semiconductor chip 100. The first semiconductor chip 201 may include a first semiconductor substrate 210a, a first through electrode 220a, a first circuit layer 230a, a first lower pad 240a, a first lower protective layer 250a, a first upper pad 260a, and a first upper protective layer 270a, which are substantially the same as those described above.

The first semiconductor chip 201 may be mounted on the lower semiconductor chip 100. The first lower protective layer 250a of the first semiconductor chip 201 may be in contact with the second passivation layer 160 of the lower semiconductor chip 100. Intermetallic hybrid bonding may be formed between the first lower pad 240a and the second conductive pad 150 at an interface between the first lower protective layer 250a and the second passivation layer 160. In the present specification, hybrid bonding is a combination of two components including the same material, and at this case, an interface between the two components might not be visible.

The first through electrode 220a may be disposed in the first region R1. The first through electrode 220a may vertically overlap the first upper pad 260a and the first lower pad 240a in the first region R1.

The first upper pad 260a may extend from the first region R1 to the second region R2. The first upper pad 260a may be in contact with the first through electrode 220a in the first region R1. The first upper pad 260a may be in contact with the second lower pad 240b described below in the second region R2. Accordingly, the first upper pad 260a may connect the first through electrode 220a and the second lower pad 240b to one another. For example, the first upper pad 260a may connect components that are not vertically aligned in the semiconductor package CS1.

The second semiconductor chip 202 may be provided on an upper surface of the first semiconductor chip 201. The second semiconductor chip 202 may include a second semiconductor substrate 210b, a second through electrode 220b, a second circuit layer 230b, a second lower pad 240b, a second lower protective layer 250b, a second upper pad 260b, and a second upper protective layer 270b, which are substantially the same as those described above. An arrangement of the second through electrodes 220b in the second semiconductor chip 202 may be different from an arrangement of the first through electrodes 220a in the first semiconductor chip 201. For example, in a plan view, the second through electrodes 220b may be horizontally spaced apart from the first through electrodes 220a. Alternatively, at least one of the second through electrodes 220b might not be vertically aligned with the first through electrodes 220a.

The second semiconductor chip 202 may be mounted on the first semiconductor chip 201. The second semiconductor chip 202 and the first semiconductor chip 201 may be bonded in a face-to-back manner. For example, a lower surface, which is an active surface of the second semiconductor chip 202, and an upper surface, which is an inactive surface of the first semiconductor chip 201 may be bonded to each other. The second lower protective layer 250b of the second semiconductor chip 202 may be in contact with the first upper protective layer 270a of the first semiconductor chip 201. Intermetallic hybrid bonding may be formed between the first upper pad 260a and the second lower pad 240b at the interface between the second lower protective layer 250b and the first upper protective layer 270a. A width of the second lower pad 240b may be smaller than that of the first upper pad 260a.

The second through electrode 220b may be disposed in the second region R2. In a plan view, the second through electrode 220b may be horizontally spaced apart from the first through electrode 220a. The second through electrode 220b may vertically overlap the first upper pad 260a, the second lower pad 240b, and the second upper pad 260b in the second region R2.

The second upper pad 260b may extend from the first region R1 to the second region R2. The second upper pad 260b may be in contact with the second through electrode 220b in the second region R2. The second upper pad 260b may be in contact with a third lower pad 240c described later in the first region R1. Accordingly, the second upper pad 260b may connect the second through electrode 220b and the third lower pad 240c. The second upper pad 260b may connect components that are not vertically aligned in the semiconductor package CS1.

The third semiconductor chip 203 may be provided on an upper surface of the second semiconductor chip 202. The third semiconductor chip 203 may include a third semiconductor substrate 210c, a third through electrode 220c, a third circuit layer 230c, a third lower pad 240c, a third lower protective layer 250c, a third upper pad 260c, and a third upper protective layer 270c, which are substantially the same as those described above. An arrangement of the third through electrode 220c in the third semiconductor chip 203 may be different from the arrangement of the second through electrode 220b in the second semiconductor chip 202. For example, in a plan view, the third through electrodes 220c may be horizontally spaced apart from the second through electrodes 220b.

The third semiconductor chip 203 may be mounted on the second semiconductor chip 202. The third semiconductor chip 203 and the second semiconductor chip 202 may be mounted in a face-to-back manner. For example, a lower surface, which is an active surface of the third semiconductor chip 203, and an upper surface, which is an inactive surface of the second semiconductor chip 202 may be bonded to each other. The third lower protective layer 250c of the third semiconductor chip 203 may be in contact with the second upper protective layer 270b of the second semiconductor chip 202. Intermetallic hybrid bonding may be formed between the second upper pad 260b and the third lower pad 240c at an interface between the third lower protective layer 250c and the second upper protective layer 270b. A width of the third lower pad 240c may be smaller than that of the second upper pad 260b.

The third through electrode 220c may be disposed in the first region R1. The third through electrode 220c may vertically overlap the first through electrode 220a. The third through electrode 220c may vertically overlap the second upper pad 260b, the third upper pad 260c, and the third lower pad 240c in the first region R1. In a plan view, the third through electrode 220c may be horizontally spaced apart from the second through electrode 220b.

The third upper pad 260c may extend from the first region R1 to the second region R2. The third upper pad 260c may be in contact with the third through electrode 220c in the first region R1. The third upper pad 260c may be in contact with a fourth lower pad 340 described later in the second region R2. Accordingly, the third upper pad 260c may connect the third through electrode 220c and the fourth lower pad 340 to one another. For example, the third upper pad 260c may connect components that are not vertically aligned in the semiconductor package CS1.

The semiconductor package CS1 may further include a fourth semiconductor chip 300 disposed on an upper surface of the third semiconductor chip 203. A side surface of the fourth semiconductor chip 300 may be vertically aligned with a side surface of the third semiconductor chip 203. The fourth semiconductor chip 300 may include, for example, a memory chip. The fourth semiconductor chip 300 may include a fourth semiconductor substrate 310, a fourth circuit layer 330, a fourth lower pad 340, and a fourth lower protective layer 350 which are the substantially same as the semiconductor substrate 210, the circuit layer 230, the lower pad 240, and the lower protective layer 250 of the upper semiconductor chip 200 described above. The fourth circuit layer 330 may include an insulating layer 331 and a wiring pattern 332 connected to the fourth lower pad 340 within the insulating layer 331.

The fourth semiconductor chip 300 may be mounted on the third semiconductor chip 203. The fourth lower protective layer 350 of the fourth semiconductor chip 300 may be in contact with the third upper protective layer 270c of the third semiconductor chip 203. Intermetallic hybrid bonding may be formed between the fourth lower pad 340 and the third upper pad 260c at an interface between the fourth lower protective layer 350 and the third upper protective layer 270c. A width of the fourth lower pad 340 may be smaller than that of the third upper pad 260c.

FIGS. 4 to 6 are plan views illustrating upper pads of a semiconductor package according to embodiments of the present disclosure. The upper pads 261, 262, and 263 described with reference to FIGS. 4 to 6 may be other embodiments of the planar shape of the upper pad 260 described with reference to FIGS. 1 to 3.

Referring to FIG. 4, an upper pad 261 may have pad portions 261p and a connection portion 261c connecting the pad portions 261p. A diameter of each of the pad portions 261p may be greater than a width of the connection portion 261c. In this case, a planar shape of the upper pad 261 may be a dumbbell shape.

Referring to FIG. 5, an upper pad 262 may have pad portions 262p and a connection portion 262c connecting the pad portions 262p. Each of the pad portions 262p may have a different diameter.

Referring to FIG. 6, an upper pad 263 may have pad portions 263p and a connection portion 263c connecting the pad portions 263p. A planar shape of the pad portions 263p may be a quadrilateral. The present disclosure is not necessarily limited thereto, and the planar shape of the pad portions 263p may include another polygonal shape.

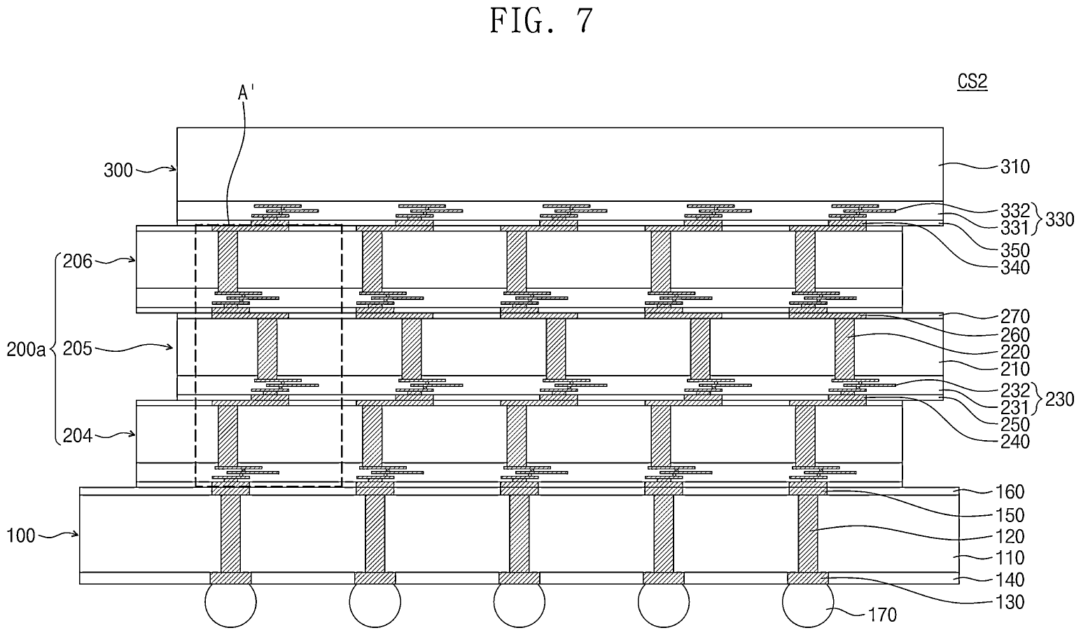

FIG. 7 is a cross-sectional view of a semiconductor package according to embodiments of the present disclosure. Hereinafter, for convenience of explanation, the same reference numerals may be provided to the same configurations, and to the extent that an element is not described in detail with respect to this figure, it may be understood that the element is at least similar to a corresponding element that has been described elsewhere within the instant disclosure. An enlarged view of region ‘A’ of FIG. 7 may be substantially the same as that shown in FIG. 2.

Referring to FIG. 7, a semiconductor package CS2 may include a lower semiconductor chip 100, upper semiconductor chips 200a, and a fourth semiconductor chip 300, which are substantially the same as the lower semiconductor chip 100, the upper semiconductor chips 200, and the fourth semiconductor chip 300 of the semiconductor package CS1 described with reference to FIGS. 1 to 3. An arrangement of the upper semiconductor chips 200a of the semiconductor package CS2 may be different from that of the embodiment of FIG. 1.

The upper semiconductor chips 200a may include a first semiconductor chip 204, a second semiconductor chip 205, and a third semiconductor chip 206. An arrangement of the through electrodes 220 may be substantially the same in each of the first semiconductor chip 204, the second semiconductor chip 205, and the third semiconductor chip 206. The upper semiconductor chips 200a may be stacked on the lower semiconductor chip 100 in a zigzag pattern. The second semiconductor chip 205 may expose a portion of an upper surface of the first semiconductor chip 204. The third semiconductor chip 206 may expose a portion of an upper surface of the second semiconductor chip 205. The fourth semiconductor chip 300 may expose a portion of an upper surface of the third semiconductor chip 206.

Two adjacent upper semiconductor chips 200a may be electrically connected to each other. For example, as described with reference to FIGS. 1 and 3, the first upper pad 260a of the first semiconductor chip 201 may be in contact with the first through electrode 220a in the first region R1. The first upper pad 260a may be in contact with the second lower pad 240b of the second semiconductor chip 202 in the second region R2. The first upper pad 260a has a connection portion extending from the first region R1 to the second region R2, and thus two adjacent upper semiconductor chips 200a may be electrically connected to each other.

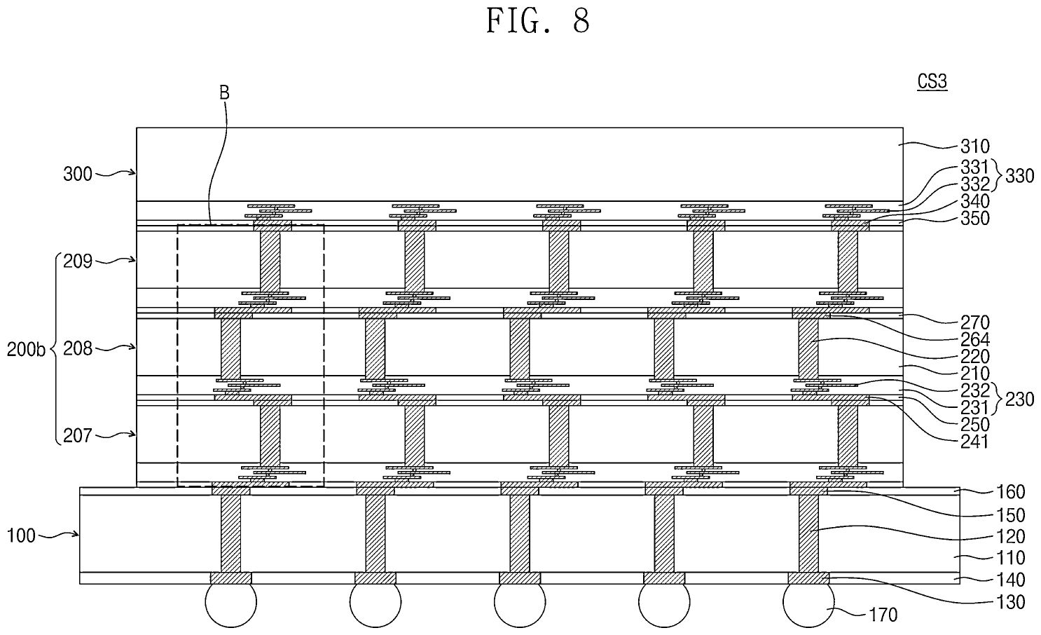

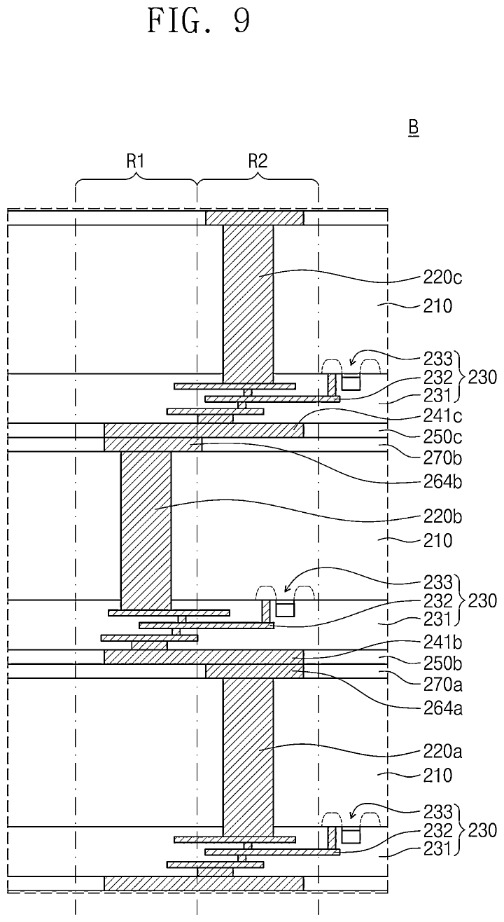

FIG. 8 is a cross-sectional view of a semiconductor package according to embodiments of the present disclosure. FIG. 9 is an enlarged view of region ‘B’ of FIG. 8. Hereinafter, for convenience of explanation, the same reference numerals may be provided to the same configurations, and to the extent that an element is not described in detail with respect to this figure, it may be understood that the element is at least similar to a corresponding element that has been described elsewhere within the instant disclosure.

Referring to FIGS. 8 and 9, a semiconductor package CS3 may include a lower semiconductor chip 100 and a fourth semiconductor chip 300 which are substantially the same as those of the semiconductor package CS1 described with reference to FIGS. 1 to 3. The upper semiconductor chips 200b of the semiconductor package CS3 may include a semiconductor substrate 210, a through electrode 220, a circuit layer 230, an upper protective layer 270, and a lower protective layer 250 which are substantially the same as those of the upper semiconductor chips 200 of the semiconductor package CS1, but structure of an upper pad 264 and a lower pad 241 may be different. Unlike the embodiments of FIGS. 1 to 3, a width of the upper pad 264 of each of the upper semiconductor chips 200b may be smaller than that of the lower pad 241.

A first through electrode 220a vertically penetrating the first semiconductor chip 207 in the first region R1 may be provided. A first upper pad 264a may be provided on an upper surface of the first through electrode 220a. The first upper pad 264a may connect the first through electrode 220a and a second lower pad 241b to one another in the first region R1 in a manner that is described later .

A second semiconductor chip 208 may be mounted on the first semiconductor chip 207. Intermetallic hybrid bonding may be formed between the first upper pad 264a and the second lower pad 241b at an interface between the first upper protective layer 270a of the first semiconductor chip 207 and the second lower protective layer 250b of the second semiconductor chip 208. A width of the second lower pad 241b may be greater than that of the first upper pad 264a. The second lower pad 241b may extend from the first region R1 to the second region R2. The second lower pad 241b may vertically overlap the second through electrode 220b in the first region R1. The lower pad 241b may be electrically connected to the second through electrode 220b. The second lower pad 241b may be in contact with the first upper pad 264a in the second region R2. The second lower pad 241b may be connected to the first through electrode 220a through the first upper pad 264a in the second region R2. Accordingly, the first through electrode 220a and the second through electrode 220b that do not vertically overlap may be electrically connected through the second lower pad 241b.

A third semiconductor chip 209 may be mounted on the second semiconductor chip 208. Intermetallic hybrid bonding may be formed between a second upper pad 264b and a third lower pad 241c at an interface between the second upper protective layer 270b and the third lower protective layer 250c. A width of the third lower pad 241c may be greater than that of the second upper pad 264b. The third lower pad 241c may extend from the first region R1 to the second region R2. The third lower pad 241c may vertically overlap the third through electrode 220c in the second region R2. The third lower pad 241c may be electrically connected to the third through electrode 220c. The third lower pad 241c may be in contact with the second upper pad 264b in the first region R1. The third lower pad 241c may be connected to the second through electrode 220b through the second upper pad 264b in the first region R1. Accordingly, the second through electrode 220b and the third through electrode 220c may be electrically connected through the third lower pad 241c.

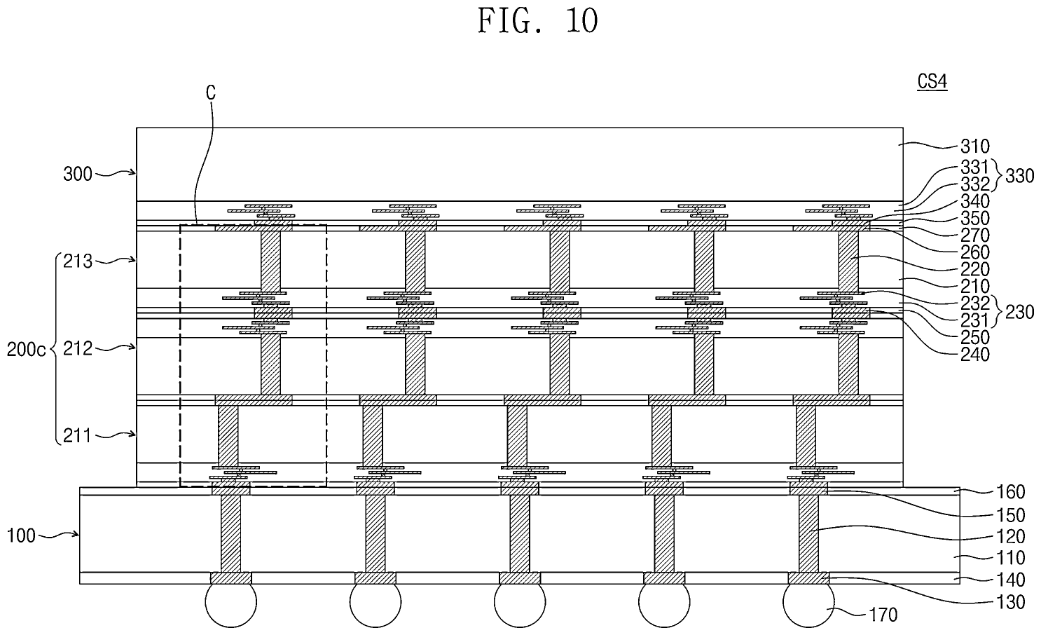

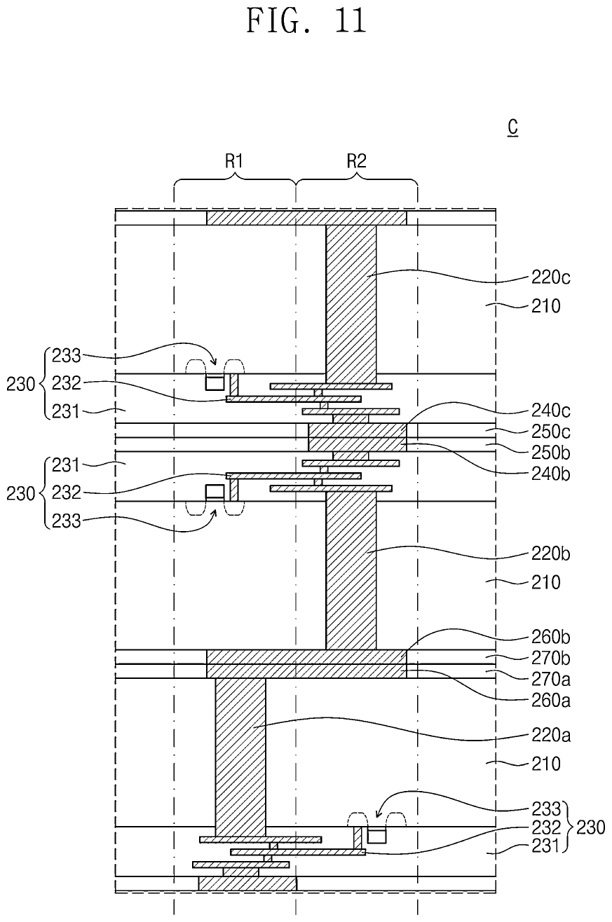

FIG. 10 is a cross-sectional view of a semiconductor package according to embodiments of the present disclosure. FIG. 11 is an enlarged view of region ‘C’ of FIG. 10. Hereinafter, for convenience of explanation, the same reference numerals may be provided to the same configurations, and to the extent that an element is not described in detail with respect to this figure, it may be understood that the element is at least similar to a corresponding element that has been described elsewhere within the instant disclosure. In addition, among components of a semiconductor chip described with reference to FIGS. 10 and 11, what is referred to as a lower protective layer and a lower pad may be adjacent to an active surface of a semiconductor chip, and what is referred to as an upper protective layer and an upper pad may be adjacent to an inactive surface of the semiconductor chip.

Referring to FIGS. 10 and 11, a semiconductor package CS4 may include a lower semiconductor chip 100 and a fourth semiconductor chip 300 substantially the same as those of the semiconductor package CS1 described with reference to FIGS. 1 to 3. The upper semiconductor chips 200c of the semiconductor package CS3 include a semiconductor substrate 210, a through electrode 220, a circuit layer 230, an upper pad 260, a lower pad 240, an upper protective layer 270, and a lower protective layer 250 substantially the same as those of the upper semiconductor chips 200 of the semiconductor package CS1. The upper semiconductor chips 200c may have different bonding manner between the semiconductor chips from that of the embodiments of FIGS. 1 to 3.

The upper semiconductor chips 200c may include a first semiconductor chip 211, a second semiconductor chip 212, and a third semiconductor chip 213.

The second semiconductor chip 212 may be mounted on the first semiconductor chip 211. The first semiconductor chip 211 and the second semiconductor chip 212 may be bonded in a back-to-back manner. For example, an inactive surface of the first semiconductor chip 211 and an inactive surface of the second semiconductor chip 212 may be bonded to one another. The first upper protective layer 270a of the first semiconductor chip 211 and the second upper protective layer 270b of the second semiconductor chip 212 may be in contact with each other. Intermetallic hybrid bonding may be formed between the first upper pad 260a and the second upper pad 260b at an interface between the first upper protective layer 270a and the second upper protective layer 270b. The first upper pad 260a and the second upper pad 260b may have substantially the same width. The first upper pad 260a and the second upper pad 260b may extend from the first region R1 to the second region R2. The first upper pad 260a may be in contact with the first through electrode 220a in the first region R1. The second upper pad 260b may be in contact with the second through electrode 220b in the second region R2. Accordingly, the first through electrode 220a and the second through electrode 220b that are not vertically aligned may be connected through the first upper pad 260a and the second upper pad 260b.

The third semiconductor chip 213 may be mounted on the second semiconductor chip 212. The third semiconductor chip 213 and the second semiconductor chip 212 may be mounted in a face-to-face manner. For example, an active surface of the second semiconductor chip 212 and an active surface of the third semiconductor chip 213 may be bonded. The second lower protective layer 250b of the second semiconductor chip 212 and the third lower protective layer 250c of the third semiconductor chip 213 may be in contact with each other. Intermetallic hybrid bonding may be formed between the second lower pad 240b and the third lower pad 240c at an interface between the second lower protective layer 250b and the third lower protective layer 250c. The second through electrode 220b, the third through electrode 220c, the second lower pad 240b, and the third lower pad 240c may vertically overlap each other in the second region R2.

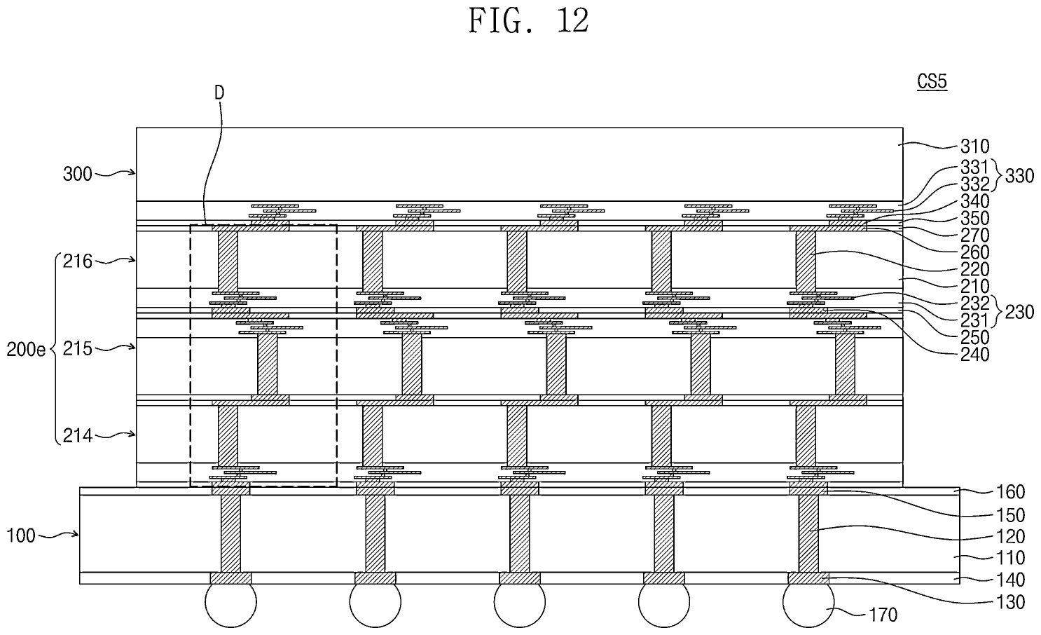

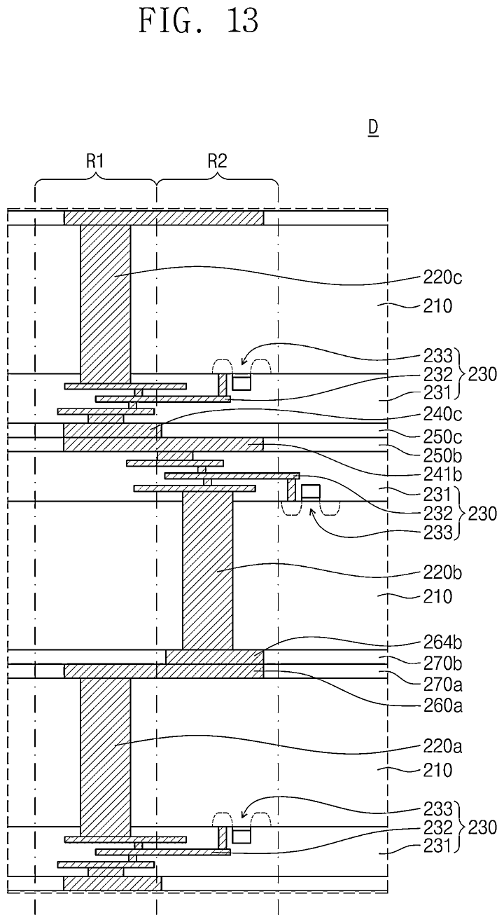

FIG. 12 is a cross-sectional view of a semiconductor package according to embodiments of the present disclosure. FIG. 13 is an enlarged view of region ‘D’ of FIG. 12. Hereinafter, for convenience of explanation, the same reference numerals may be provided to the same configurations, and to the extent that an element is not described in detail with respect to this figure, it may be understood that the element is at least similar to a corresponding element that has been described elsewhere within the instant disclosure. In addition, among components of a semiconductor chip described with reference to FIGS. 12 and 13, what is referred to as a lower protective layer and a lower pad may be adjacent to an active surface of a semiconductor chip, and what is referred to as an upper protective layer and an upper pad may be adjacent to an inactive surface of the semiconductor chip.

Referring to FIG. 12, a semiconductor package CS5 may include a lower semiconductor chip 100 and a fourth semiconductor chip 300 substantially the same as those of the semiconductor package CS1 described with reference to FIGS. 1 to 3. An upper semiconductor chip 200e of the semiconductor package CS5 may include a first semiconductor chip 214, a second semiconductor chip 215, and a third semiconductor chip 216. The first semiconductor chip 214 and the third semiconductor chip 216 may be substantially the same as the first semiconductor chip 201 described with reference to FIG. 1. The second semiconductor chip 215 may be substantially the same as the first semiconductor chip 207 described with reference to FIG. 8, but a bonding manner between adjacent semiconductor chips may be different.

The second semiconductor chip 215 may be mounted on the first semiconductor chip 214. The first semiconductor chip 214 and the second semiconductor chip 215 may be bonded in a back-to-back manner. For example, an inactive surface of the first semiconductor chip 214 and an inactive surface of the second semiconductor chip 215 may be bonded. The first upper protective layer 270a of the first semiconductor chip 214 and the second upper protective layer 270b of the second semiconductor chip 215 may be in contact with each other. Intermetallic hybrid bonding may be formed between the first upper pad 260a and the second upper pad 264b at an interface between the first upper protective layer 270a and the second upper protective layer 270b. A width of the first upper pad 260a may be greater than that of the second upper pad 264b. The first upper pad 260a may extend from the first region R1 to the second region R2. The first upper pad 260a may be in contact with the first through electrode 220a in the first region R1. The first upper pad 260a may be in contact with the second upper pad 264b in the second region R2. The first upper pad 260a may connect the first through electrode 220a and the second upper pad 264b to one another. The first upper pad 260a may be connected to the second through electrode 220b through the second upper pad 264b in the second region R2. Accordingly, the first upper pad 260a may electrically connect the first through electrode 220a and the second through electrode 220b. The first upper pad 260a may connect components that are not vertically aligned in the semiconductor package CS5.

The third semiconductor chip 216 may be mounted on the second semiconductor chip 215. The second semiconductor chip 215 and the third semiconductor chip 216 may be bonded in a face-to-face manner. For example, an active surface of the second semiconductor chip 215 and an active surface of the third semiconductor chip 216 may be bonded to one another. The second lower protective layer 250b of the second semiconductor chip 215 and the third lower protective layer 250c of the third semiconductor chip 216 may be in contact with each other. Intermetallic hybrid bonding may be formed between the second lower pad 241b and the third lower pad 240c at an interface between the second lower protective layer 250b and the third lower protective layer 250c. A width of the second lower pad 241b may be greater than that of the third lower pad 240c. The second lower pad 241b may extend from the first region R1 to the second region R2. The second lower pad 241b may vertically overlap the third through electrode 220c and the third lower pad 240c in the first region R1. The second lower pad 241b may be in contact with the third lower pad 240c in the first region R1. The second lower pad 241b may vertically overlap the second through electrode 220b in the second region R2. The second lower pad 241b may be electrically connected to the second through electrode 220b. The second lower pad 241b may electrically connect the second through electrode 220b and the third through electrode 220c.

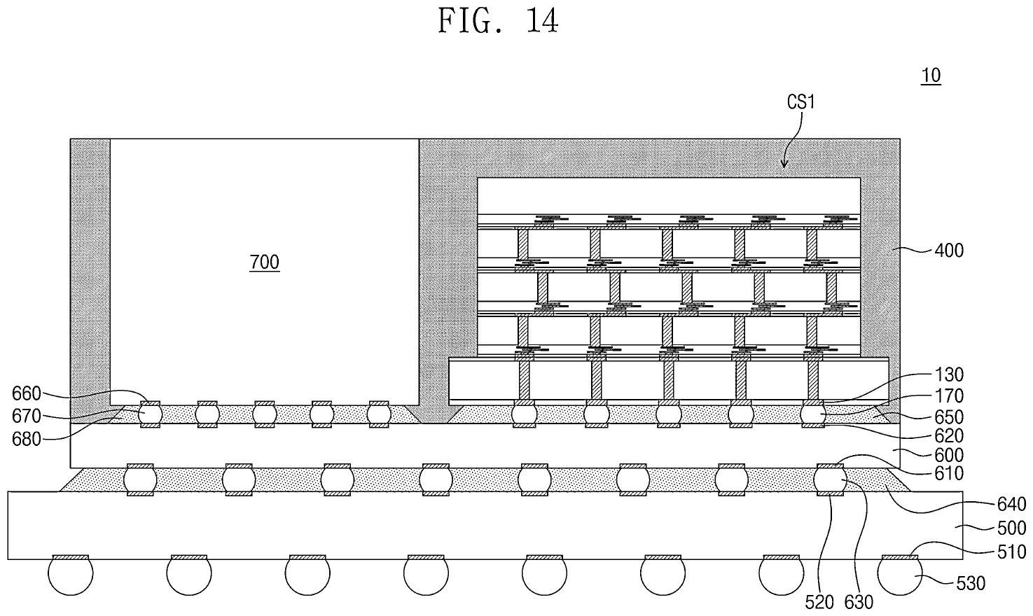

FIG. 14 is a cross-sectional view of a semiconductor package according to embodiments of the present disclosure. Hereinafter, for convenience of explanation, the same reference numerals may be provided to the same configurations, and to the extent that an element is not described in detail with respect to this figure, it may be understood that the element is at least similar to a corresponding element that has been described elsewhere within the instant disclosure.

Referring to FIG. 14, a semiconductor package 10 may include a package substrate 500, an interposer substrate 600, a semiconductor device 700, and a chip stack CS1. The chip stack CS1 may be substantially the same as the semiconductor package CS1 shown in FIG. 1, but the present disclosure is not necessarily limited thereto. The chip stack may include one of the semiconductor packages shown in FIGS. 7, 8, 10, and 13.

The package substrate 500 may be a printed circuit board including wiring patterns printed on upper and lower surfaces thereof. Alternatively, the package substrate 500 may be a redistribution substrate including a plurality of insulating layers stacked on each other and a wiring layer within the insulating layers. First upper substrate pads 520 may be disposed on an upper surface of the package substrate 500. The first upper substrate pads 520 may be exposed on the upper surface of the package substrate 500. First lower substrate pads 510 may be disposed on a lower surface of the package substrate 500. The first lower substrate pads 510 may be exposed on the lower surface of the package substrate 500. The first upper substrate pads 520 and the first lower substrate pads 510 may be electrically connected through a wiring layer in the package substrate 500. The first upper substrate pads 520 and the first lower substrate pads 510 may include a conductive material such as copper (Cu), aluminum (Al), and/or nickel (Ni).

External connection terminals 530 may be disposed on the lower surface of the package substrate 500. The external connection terminals 530 may be disposed on the first lower substrate pads 510. The external connection terminals 530 may include solder balls or solder bumps. The external connection terminals 530 may be one of tin (Sn), silver (Ag), copper (Cu), nickel (Ni), bismuth (Bi), indium (In), antimony (Sb), or cerium (Ce), or alloys thereof. Depending on the type of external connection terminals 530, the semiconductor package 10 may be a ball grid array (BGA) form, a fine ball-grid array (FBGA) form, or a land grid array (land grid array). LGA) form.

The interposer substrate 600 may be provided on the package substrate 500. Second upper substrate pads 620 may be disposed on an upper surface of the interposer substrate 600. The second upper substrate pads 620 may be exposed on the upper surface of the interposer substrate 600. Second lower substrate pads 610 may be disposed on a lower surface of the interposer substrate 600. The second lower substrate pads 610 may be exposed on the lower surface of the interposer substrate 600. The second upper substrate pads 620 and the second lower substrate pads 610 may be electrically connected through a wiring layer provided in the interposer substrate 600. Unlike what is illustrated in FIG. 14, the second upper substrate pads 620 may be vertically aligned with the second lower substrate pads 610, and through electrodes may be provided to connect the second upper substrate pads 620 and the second lower substrate pads 610 to one another.

The interposer substrate 600 may be mounted on the package substrate 500 in a flip chip manner. For example, the interposer substrate 600 may be mounted on the package substrate 500 through substrate connection terminals 630 provided between the first upper substrate pads 520 and the second lower substrate pads 610. The substrate connection terminals 630 may include solder balls or solder bumps. The substrate connection terminals 630 may be one of tin (Sn), silver (Ag), copper (Cu), nickel (Ni), bismuth (Bi), indium (In), antimony (Sb), or cerium (Ce), or alloys thereof.

A first underfill 640 may be provided between the interposer substrate 600 and the package substrate 500. The first underfill 640 may at least partially surround the substrate connection terminals 630 and fill between the substrate connection terminals 630.

The semiconductor device 700 may be provided on the interposer substrate 600. The semiconductor device 700 may include a logic chip or a buffer chip. The logic chip may include an ASIC chip or an application processor (AP) chip. Alternatively, the logic chip may include a central processing unit (CPU) or a graphics processing unit (GPU). The ASIC chip may include an application specific integrated circuit (ASIC). Alternatively, the semiconductor device 700 may be a memory chip.

The semiconductor device 700 may include chip pads 660 exposed on a lower surface of the semiconductor device 700. The chip pads 660 may be electrically connected to an integrated circuit in the semiconductor device 700. The chip pads 660 may include a conductive material. For example, the chip pads 660 may include a metal such as copper (Cu).

The semiconductor device 700 may be mounted on the interposer substrate 600 in a flip chip manner. For example, it may be mounted on the interposer substrate 600 through second chip connection terminals 670 provided between the chip pads 660 and the second upper substrate pads 620. The second chip connection terminals 670 may include solder balls or solder bumps. The second chip connection terminals 670 may include one of tin (Sn), silver (Ag), copper (Cu), nickel (Ni), bismuth (Bi), indium (In), antimony (Sb), or cerium (Ce), or an alloy thereof.

A second underfill 680 may be provided between the semiconductor device 700 and the interposer substrate 600. The second underfill 680 may at least partially surround the second chip connection terminals 670 and fill the spaces between the second chip connection terminals 670.

The chip stack CS1 may be provided on the interposer substrate 600. The chip stack CS1 may be horizontally spaced apart from the semiconductor device 700 on the interposer substrate 600. The chip stack CS1 may be mounted on the interposer substrate 600 in a flip chip manner. The chip stack CS1 may be mounted on the interposer substrate 600 through the first chip connection terminal 170. The chip stack CS1 and the semiconductor device 700 may be electrically connected through the interposer substrate 600.

A fourth underfill 650 may be provided between the chip stack CS1 and the interposer substrate 600. The fourth underfill 650 may fill between the chip stack CS1 and the interposer substrate 600 and at least partially surround the first chip connection terminal 170.

A molding layer 400 may be provided on the interposer substrate 600. The molding layer 400 may cover an upper surface of the interposer substrate 600 and may at least partially surround the semiconductor device 700 and the chip stack CS1. The molding layer 400 may include an insulating polymer such as an epoxy-based molding compound.

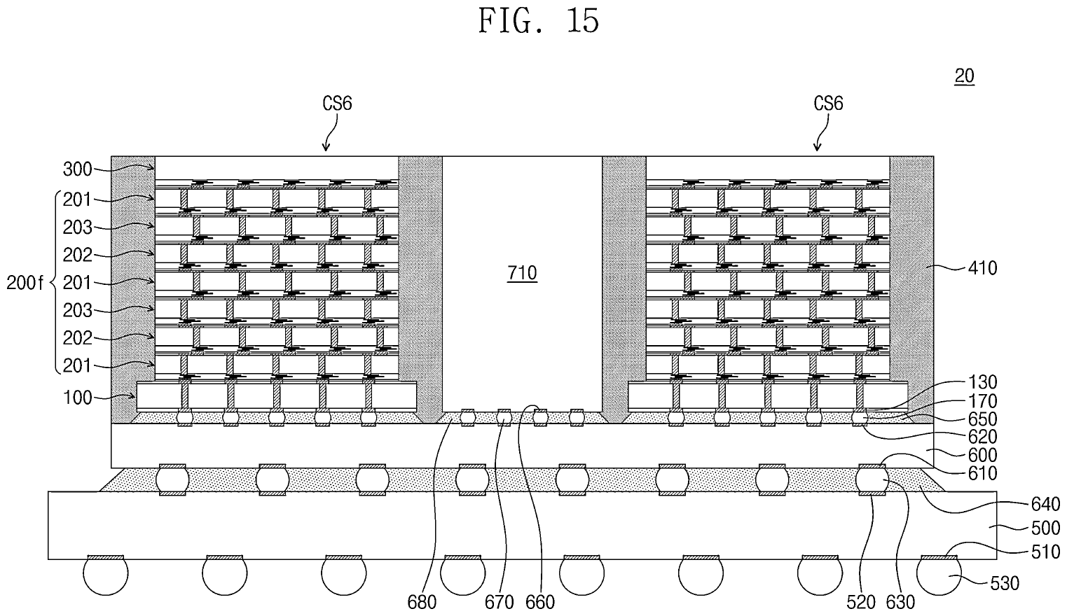

FIG. 15 is a cross-sectional view of a semiconductor package according to embodiments of the present disclosure. Hereinafter, for convenience of explanation, the same reference numerals may be provided to the same configurations, and to the extent that an element is not described in detail with respect to this figure, it may be understood that the element is at least similar to a corresponding element that has been described elsewhere within the instant disclosure.

Referring to FIG. 15, a semiconductor package 20 may include a package substrate 500, an interposer substrate 600, a semiconductor device 710, and chip stacks CS6. The package substrate 500, the interposer substrate 600, and the semiconductor device 710 may be substantially the same as those described with reference to FIG. 14.

The chip stacks CS6 may be provided on the interposer substrate 600.

The chip stacks CS6 may be spaced apart from each other. Each of the chip stacks CS6 may include eight upper semiconductor chips 200f stacked on the lower semiconductor chip 100. The upper semiconductor chips 200f may include a plurality of first semiconductor chip 201, a plurality of second semiconductor chips 202, and a plurality of third semiconductor chips 203 of the semiconductor package CS1 described with reference to FIG. 1, which are stacked. However, the present disclosure is not necessarily limited thereto, and the chip stacks CS6 may include one of the semiconductor packages of FIGS. 1, 7, 8, 10, and 12, or a combination thereof. The chip stacks CS6 may be disposed on the interposer substrate 600 in the same manner as the mounting manner of the chip stack CS1 described with reference to FIG. 14.

The semiconductor device 710 may be disposed between the chip stacks CS6. The semiconductor device 710 may be disposed on the interposer substrate 600 in the same manner as the mounting manner of the semiconductor device 700 described with reference to FIG. 14.

A molding layer 410 may be provided on the interposer substrate 600 to at least partially surround the semiconductor device 710 and the chip stacks CS6. As illustrated in FIG. 15, the molding layer 410 may expose upper surfaces of the semiconductor device 710 and chip stacks CS6, but otherwise, the molding layer 410 may cover the semiconductor device 710 and the chip stacks CS6.

The semiconductor package, according to embodiments, may include the upper pad on the upper surface of the semiconductor chip and the lower pad on the lower surface of a semiconductor chip, and the upper pad may have the greater width than the lower pad. Thus, when bonding the semiconductor chips, the degree of freedom in the arrangement of the semiconductor chips and the arrangement of the through electrodes may be increased. Accordingly, it may be possible to bond the semiconductor chips having different through electrode arrangements. In addition, it may be possible to arrange the semiconductor chips in the zigzag shape. Accordingly, the productivity of the semiconductor package may be improved.

While embodiments of the present disclosure are described above, a person skilled in the art may understand that many modifications and variations are made without departing from the spirit and scope of the present disclosure.

What is claimed is:

1. A semiconductor package, comprising:
a lower semiconductor chip;
a first semiconductor chip stacked on the lower semiconductor chip; and
a second semiconductor chip stacked on the lower semiconductor chip,
wherein the first semiconductor chip includes:
a first semiconductor substrate;
a first through electrode vertically penetrating the first semiconductor substrate;
a first upper pad electrically connected to the first through electrode on an upper surface of the first semiconductor substrate;
an upper protective layer at least partially surrounding the first upper pad on the upper surface of the first semiconductor substrate;
a first circuit layer disposed on a lower surface of the first semiconductor substrate; and
a first lower pad connected to the first through electrode through the first circuit layer on a lower surface of the first circuit layer,
wherein the second semiconductor chip includes:
a second semiconductor substrate;
a second through electrode vertically penetrating the second semiconductor substrate;
a second upper pad electrically connected to the second through electrode on an upper surface of the second semiconductor substrate;
a second circuit layer disposed on a lower surface of the second semiconductor substrate;
a second lower pad electrically connected to the second through electrode through the second circuit layer on a lower surface of the second circuit layer; and
a lower protective layer at least partially surrounding the second lower pad on the lower surface of the second circuit layer,
wherein the lower protective layer is in direct contact with the upper protective layer,
wherein the second lower pad is in contact with the first upper pad and forms an integral body therewith, and
wherein the first through electrode is horizontally spaced apart from the second through electrode, in a plan view.

2. The semiconductor package of claim 1, wherein a width of the first upper pad is greater than a width of the second lower pad.

3. The semiconductor package of claim 1, wherein each of the first upper pad and the second upper pad includes pad portions horizontally spaced apart from each other and a connection portion electrically connecting the pad portions.

4. The semiconductor package of claim 3, wherein a width of the connection portion is equal to or smaller than a diameter of each of the pad portions.

5. The semiconductor package of claim 3, wherein a diameter of each of the pad portions is greater than a diameter of each of the first through electrode and the second through electrode.

6. The semiconductor package of claim 1, wherein the first through electrode and the second through electrode are each provided in plural, and
wherein an arrangement of the first through electrodes in the first semiconductor chip is equal to an arrangement of the second through electrodes in the second semiconductor chip.

7. The semiconductor package of claim 1, wherein the first through electrode and the second through electrode are each provided in plural, and
wherein an arrangement of the first through electrodes in the first semiconductor chip is different from an arrangement of the second through electrodes in the second semiconductor chip.

8. The semiconductor package of claim 1, wherein the first upper pad includes a first region and a second region horizontally spaced apart from the first region,
wherein the first through electrode vertically overlaps the first region of the first upper pad, and
wherein the second through electrode vertically overlaps the second region of the first upper pad.

9. The semiconductor package of claim 1, wherein the second semiconductor chip exposes a portion of the upper surface of the first semiconductor chip.

10. The semiconductor package of claim 1, wherein a side surface of the first semiconductor chip and a side surface of the second semiconductor chip are vertically aligned.

11. A semiconductor package, comprising:
a first semiconductor chip; and
a second semiconductor chip disposed on the first semiconductor chip,
wherein the first semiconductor chip includes:
an upper pad disposed on an upper surface of the first semiconductor chip; and
a first through electrode vertically penetrating the first semiconductor chip and electrically connected to the upper pad,
wherein the second semiconductor chip includes:
a lower pad disposed on a lower surface of the second semiconductor chip; and
a second through electrode vertically penetrating the second semiconductor chip and electrically connected to the lower pad,
wherein the first through electrode is provided on a first region,
wherein the second through electrode is provided on a second region horizontally spaced apart from the first region, and
wherein a width of the upper pad is greater than a width of the lower pad.

12. The semiconductor package of claim 11, wherein the upper surface of the first semiconductor chip and a lower surface of the second semiconductor chip are in contact with each other, and
wherein the upper pad is in contact with the lower pad and forms an integral body therewith.

13. The semiconductor package of claim 11, wherein the upper pad includes:
pad portions having a larger diameter than a diameter of each of the first through electrode and the second through electrode, the pad portions being horizontally spaced apart from each other; and
a connection portion disposed between the pad portions.

14. The semiconductor package of claim 13, wherein a width of the connection portion is smaller than a diameter of each of the pad portions.

15. The semiconductor package of claim 13, wherein each of the pad portions has a different diameter from each other.

16. The semiconductor package of claim 11, wherein a side surface of the first semiconductor chip is vertically aligned with a side surface of the second semiconductor chip.

17. The semiconductor package of claim 11, wherein the second semiconductor chip exposes a portion of the upper surface of the first semiconductor chip.

18. A semiconductor package, comprising:
a lower semiconductor chip; and
upper semiconductor chips stacked in a zigzag form on the lower semiconductor chip,
wherein the upper semiconductor chips include a first semiconductor chip and a second semiconductor chip disposed on the first semiconductor chip,
wherein the first semiconductor chip includes:
a first upper pad disposed on an upper surface of the first semiconductor chip;
a first lower pad disposed on a lower surface of the first semiconductor chip; and
a first through electrode vertically penetrating the first semiconductor chip and electrically connecting the first upper pad and the first lower pad to each other,
wherein the second semiconductor chip includes:
a second upper pad disposed on an upper surface of the second semiconductor chip;
a second lower pad disposed on a lower surface of the second semiconductor chip, the second lower pad having a smaller width than the first upper pad; and
a second through electrode vertically penetrating the second semiconductor chip and electrically connecting the second upper pad and the second lower pad to each other, and
wherein the first upper pad and the second lower pad are in direct contact with each other and forms an integral body therewith.

19. The semiconductor package of claim 18, wherein, in a plan view, the first through electrode and the second through electrode are horizontally spaced apart from each other, and the first upper pad extends from the first through electrode to the second through electrode.

20. The semiconductor package of claim 18, wherein the first through electrode and the second through electrode are each provided in plural, and
wherein at least one of the first through electrodes is horizontally spaced apart from the second through electrodes, in a plan view.
